(19) United States
(12) Patent Application Publication
(10) Pub. No.: US 2013/0056860 A1
(43) Pub. Date: Mar. 7, 2013

(54) RESIN-ENCAPSULATED SEMICONDUCTOR DEVICE

(71) Applicant: Yohei NAGASAKI, Tokyo (JP)

(72) Inventor: Yohei NAGASAKI, Tokyo (JP)

(73) Assignee: Kabushiki Kaisha Toshiba, Tokyo (JP)

(21) Appl. No.: 13/415,090

(22) Filed: Mar. 8, 2012

(30) Foreign Application Priority Data
Sep. 7, 2011 (JP) 2011-195056

(51) Int. Cl. H01L 23/495

(52) U.S. Cl. 257/669; 257/E23.052

(57) ABSTRACT

According to one embodiment, a resin-encapsulated semiconductor includes a base a semiconductor chip provided on the base, stress relief members provided on the base and out side semiconductor chip, and each of the stress relief members relieving stress applied to the semiconductor chip.

### CROSS REFERENCE TO RELATED APPLICATION

This application is based upon and claims the benefit of priority from prior Japanese Patent Application No. 2011-195056, filed on Sep. 7, 2011, the entire contents of which are incorporated herein by reference.

### FIELD

Exemplary embodiment described herein generally relates to a resin-encapsulated semiconductor device.

### BACKGROUND

In a resin-encapsulated semiconductor device, there is a large difference in the coefficient of thermal expansion between a mold resin and a semiconductor chip. For this reason, thermal stress is induced due to the heat generated because of a change in an external environment or energization, and the stress is applied to the semiconductor chip from the mold resin.

The aforementioned stress is dominantly applied to corner portions of the semiconductor chip.

Application of such stress to the semiconductor chip causes a problem which an upper layer metal of the semiconductor chip may have a trouble such as rupture or peeling of the metal.

### BRIEF DESCRIPTION OF THE DRAWINGS

FIG. 1 is a schematic plan view showing a configuration example of a semiconductor device according to an embodiment;

FIG. 2 is an explanatory diagram of the stress applied to a semiconductor chip according to the embodiment;

FIG. 3 is a schematic cross-sectional view showing distribution of the stress in the semiconductor device according to the embodiment;

FIG. 4 is a schematic plan view showing another example of shapes of stress relief members of a semiconductor device according to the embodiment;

FIG. 5 is a schematic plan view showing yet another example of shapes of stress relief members of a semiconductor device according to the embodiment; and

FIG. 6 is a schematic plan view showing still another example of a shape of a stress relief member of a semiconductor device according to the embodiment.

### DETAILED DESCRIPTION

According to one embodiment, a resin-encapsulated semiconductor includes abase a semiconductor chip provided on the base, stress relief members provided on the base and out side semiconductor chip, and each of the stress relief members relieving stress applied to the semiconductor chip.

Embodiments will be described below with reference to the drawings.

Note that, the same reference numerals are used to denote the same or corresponding portions throughout the drawings, and the descriptions of the portions will not be repeated.

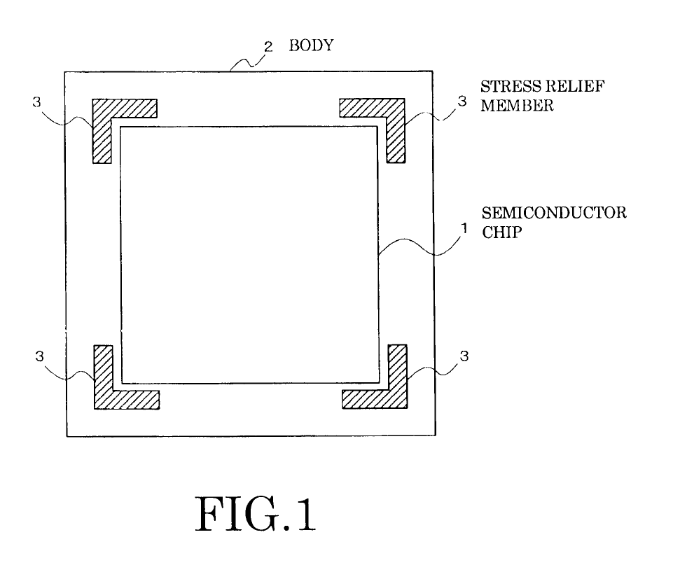

FIG. 1 is a schematic plan view showing a configuration example of a semiconductor device according to an embodiment. The semiconductor device of the embodiment is encapsulated by a mold resin. FIG. 1 shows the semiconductor device before the resin-encapsulation.

The semiconductor device of the embodiment includes a semiconductor chip 1, a base 2 on which the semiconductor chip 1 is placed, and stress relief members 3, which are respectively arranged on the base 2 outside all corners of the semiconductor chip 1 and are configured to relieve the stress applied to the semiconductor chip 1 from the mold resin after the resin-encapsulation.

The base 2 is a bed in the case of a lead frame and is a wiring board in the case of a BGA (Ball Grid Array) or the like.

The stress relief members 3 are arranged outside all the corners of the semiconductor chip 1 while each diagonal pair of the stress relief members 3 face each other on an extension of a diagonal line of the semiconductor chip 1. The stress relief members 3 are extended along two adjacent sides of the semiconductor chip 1 in parallel, respectively. Further, the extended portions are not restricted in parallel. An angle may be set between each of a pair of the extended portions. Meanwhile, the stress relief members 3 are arranged perpendicular to the base 2. In such a manner, the stress application to the semiconductor chip 1 due to displacement of the mold resin by expansion or the like can be suppressed. Furthermore, the stress relief members 3 can be set nearer to each of the corners of the semiconductor chip 1 in a view point of covering the corner nearly completely.

In the case where the base 2 is the bed of a lead frame, the stress relief members 3 can be formed by press forming during a fabrication process of the lead frame. In the case where the base 2 is a wiring board, the stress relief members 3 are fabricated in advance and mounted onto the base 2 by adhesive in the same manner as the semiconductor chip 1. Furthermore, a height of a portion on which the semiconductor chip 1 is set in the base 2 can be different from a height of another portion on which the stress relief members 3 is set in the base 3.

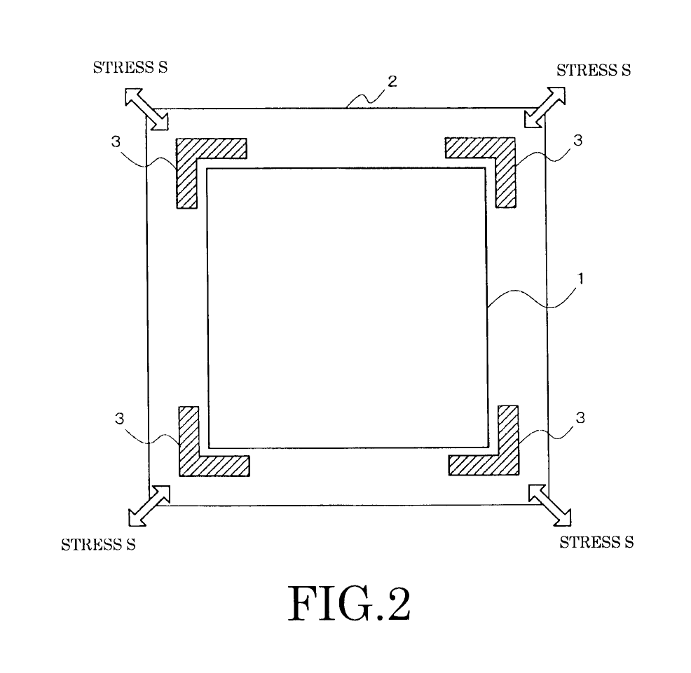

FIG. 2 shows how the stress is applied to the semiconductor chip 1 from the mold resin after the resin-encapsulation.

Stress S applied from the mold resin concentrates on the corners of the semiconductor chip 1. Moreover, the directions in which the stress S is applied are the directions of the diagonal lines of the semiconductor chip 1.

The embodiment is provided with the stress relief members 3 on the extensions of the diagonal lines of the semiconductor chip 1 and can thereby reduce the stress applied to the semiconductor chip 1.

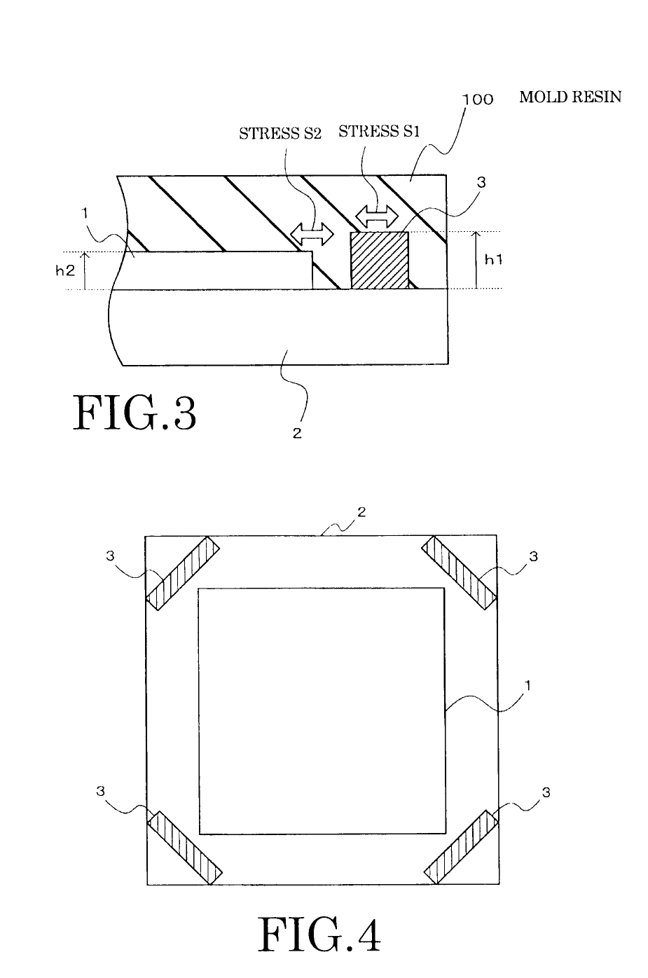

FIG. 3 is a partial cross-sectional view of the vicinity of a corner of the semiconductor device of the embodiment.

Here, the stress relief members 3 are each formed to have a height h1 larger than a height h2 of the semiconductor chip 1.

Thus, the stress S applied from the mold resin is distributed into stress S1 to the stress relief member 3 and stress S2 to the semiconductor chip 1. To put it specifically, the stress applied to the upper surface of the semiconductor chip 1 is relieved. As a result, the force to slide the upper layer metal of the semiconductor chip 1 to the inner side is so weakened that the upper layer metal can be less likely to have a trouble such as rupture or peeling. Meanwhile, the stress can be also relieved when the height h1 is the same or lower than the height h2. In this case, the stress relief member 3 has no obstacle to wire-bonding and the semiconductor device can have a lighter weight and a lower cost. Furthermore, the case of the height hl being the same or lower than the height h2 can be combined with a case in which the height of the portion on which the semiconductor chip 1 is disposed being different, for example lower, from the height of another portion on which the stress relief members 3 is disposed.

Next, various examples of the shapes of stress relief members 3 are shown in FIG. 4 to FIG. 7.

FIG. 4 shows an example in which stress relief members 3 are each formed in such a wall type that the entire surface of the stress relief member 3 can receive the stress S in the diagonal direction. The stress relief members 3 of the wall type have higher resistance to the stress S than those of the right angle type shown in FIG. 1, and thus are capable of relieving more stress applied to the semiconductor chip 1. In such case, each of the stress relief members 3 is linearly extended along two adjacent sides of the base 2, respectively. In this embodiment, the stress relief member 3 is a rectangular parallelepiped and has an angle of 45 degrees to the two adjacent sides. However, shape and angle are not restricted to the above case.

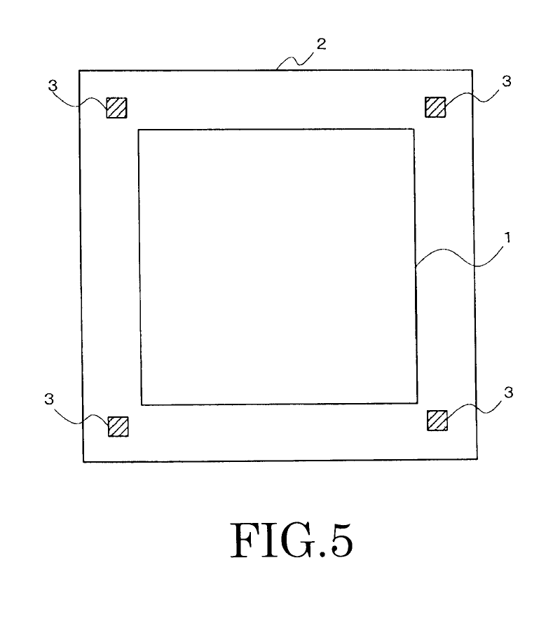

FIG. 5 shows an example in which the stress relief members 3 are each formed in a square column type. In FIG. 5, A shape in plane view can be set to be square, circle or the like. In this embodiment, the center of the stress relief members 3 is placed on the extension of the diagonal line of the semiconductor chip 1.

As shown in FIG. 2, the stress relief members 3 are higher than the semiconductor chip 1. In a case where the stress relief member 3 exists in a bonding direction for bonding of the semiconductor chip 1, the bonding needs to be performed by routing a bonding wire across the stress relief member 3. This makes the length of the bonding wire longer than in a case where no stress relief member 3 exists.

The corner portions of a chip are connected by bonding in an oblique direction in many cases. Thus, the lengths of the bonding wires for the corner portions of the chip are generally long. A longer bonding wire, however, may cause a problem such as wire sweep in molding.

In order to avoid such problem, the stress relief members 3 of the square column type shown in FIG. 5 are used. Use of the stress relief members 3 of the square column type can reduce the influence on the bonding in the corner portions of the chip.

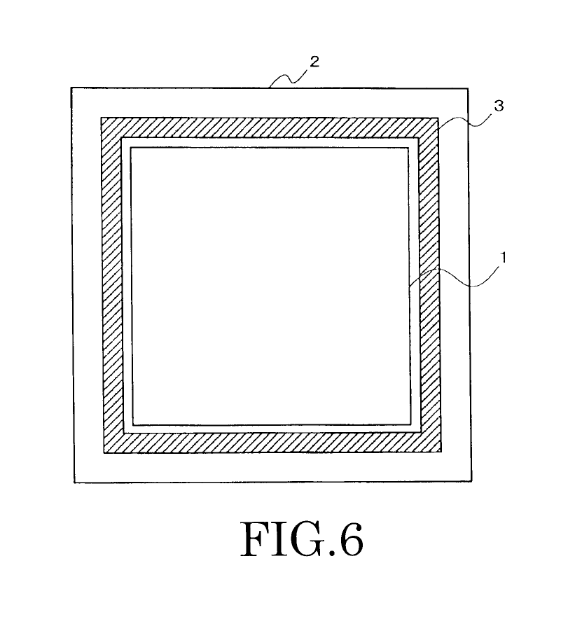

On the other hand, for a case where the aforementioned problem relating to the bonding does not exist, a stress relief member 3 may be formed in a ring type as shown in FIG. 6. The stress relief member 3 of the ring type can relieve the stress not only in the diagonal directions but also in directions other than the diagonal directions. In this case, the ring type has a closed loop, however, it is not restricted the above case. The ring type can partially include intermissive portion.

According to the embodiments, the arrangement of the stress relief members 3 outside all the corners of the semiconductor chip 1 enables relieving of the stress applied to the corners of the semiconductor chip 1 from the mold resin. This makes the upper layer metal of the semiconductor chip 1 less likely to have a trouble such as rupture or peeling.

According to the semiconductor devices of the embodiments described above, it is possible to relieve the stress applied to the semiconductor chip from the mold resin.

While certain embodiments have been described, these embodiments have been presented by way of example only, and are not intended to limit the scope of the inventions. Indeed, the novel embodiments described herein may be embodied in a variety of other forms; furthermore, various omissions, substitutions and changes in the form of the embodiments described herein may be made without departing from the spirit of the inventions. The accompanying claims and their equivalents are intended to cover such forms or modifications as would fall within the scope and spirit of the inventions.

What is claimed is:

1. A resin-encapsulated semiconductor comprising:
a base;
a semiconductor chip provided on the base; and
stress relief members provided on the base and out side semiconductor chip, each of the stress relief members relieving stress applied to the semiconductor chip.

2. The resin-encapsulated semiconductor of claim 1,
wherein stress relief members are provided on an extension of a diagonal line of the semiconductor chip to be opposed to each other.

3. The resin-encapsulated semiconductor of claim 2,
wherein a height of the stress relief member is higher than a height of the semiconductor chip.

4. The resin-encapsulated semiconductor of claim 2,
wherein a height of a portion of the base on which the semiconductor chip is disposed is different from a portion of the base on which the stress relief member is disposed.

5. The resin-encapsulated semiconductor of claim 4,
wherein the height of the stress relief member is lower than the height of the semiconductor chip.

6. The resin-encapsulated semiconductor of claim 2,
wherein the stress relief member extends along adjacent two sides of the semiconductor chip, respectively.

7. The resin-encapsulated semiconductor of claim 6,
wherein each of portions of the stress relief member extending along the adjacent sides of the semiconductor chip is set to be in parallel with each of the adjacent side.

8. The resin-encapsulated semiconductor of claim 6,
wherein each of portions of the stress relief member extending along the adjacent sides of the semiconductor chip is set to have an angle below 90 degrees to each of the adjacent sides.

9. The resin-encapsulated semiconductor of claim 8,
wherein each of portions of the stress relief member extending along the adjacent sides of the semiconductor chip is set to have an angle of 45 degrees to each of the adjacent sides.

10. The resin-encapsulated semiconductor of claim 2,
wherein the stress relief member has a column structure.

11. The resin-encapsulated semiconductor of claim 10,
wherein the stress relief member has a square column structure in a plane view.

12. The resin-encapsulated semiconductor of claim 11,
wherein the center of the square in plane view is set to be on the extension of the diagonal line of the semiconductor chip.

13. The resin-encapsulated semiconductor of claim 10,
wherein the stress relief member has a circular column structure in a plane view.

14. The resin-encapsulated semiconductor of claim 13,
wherein the center of the circle in plane view is set to be on the extension of the diagonal line of the semiconductor chip.

15. The resin-encapsulated semiconductor of claim 1,
wherein the stress relief member surrounds outside of the semiconductor chip.

16. The resin-encapsulated semiconductor of claim 15,
wherein the stress relief member surrounding outside of the semiconductor chip is constituted with a closed loop.

17. The resin-encapsulated semiconductor of claim 15,
wherein the stress relief member surrounding outside of the semiconductor chip has a intermissive portion.

18. The resin-encapsulated semiconductor of claim 1,
wherein the base is a bed of a lead frame.

19. The resin-encapsulated semiconductor of claim 1,
wherein the base is a wiring board.

20. The resin-encapsulated semiconductor of claim 1,
the stress relief members are arranged perpendicular to the base.
